(19) United States
(12) Patent Application Publication
(10) Pub. No.: US 2014/0291633 A1
(43) Pub. Date: Oct. 2, 2014

(54) FLEXIBLE SUBSTRATE AND FLEXIBLE DISPLAY DEVICE INCLUDING THE SAME

(71) Applicant: SAMSUNG DISPLAY CO., LTD., Yongin-City (KR)

(72) Inventors: Seok-Gi BAEK, Yongin-City (KR); Soon-Ryong PARK, Yongin-City (KR); Woo-Suk JUNG, Yongin-City (KR); Tae-Eun KIM, Yongin-City (KR)

(21) Appl. No.: 14/062,948

(22) Filed: Oct. 25, 2013

(30) Foreign Application Priority Data
Mar. 27, 2013 (KR) 10-2013-0033070

(51) Int. Cl. H01L 51/00; H01L 27/32

(52) U.S. Cl. CPC H01L 51/0097; H01L 27/32
USPC 257/40; 428/411.1; 428/212; 428/473.5; 428/423.1

(57) ABSTRACT

A flexible substrate includes a flexible base substrate and a first passivation layer formed on one surface of the base substrate and made of a material having a coefficient of thermal expansion lower than that of the base substrate.

### CROSS-REFERENCE TO RELATED APPLICATION

This application claims priority to and the benefit of Korean Patent Application

No. 10-2013-0033070, filed in the Korean Intellectual Property Office on Mar. 27, 2013, the entire contents of which are incorporated herein by reference.

### BACKGROUND

1. Field

Embodiments relate to a flexible substrate and a flexible display device including the same.

2. Description of the Related Art

A flat panel display device has been used as a display device replacing a cathode-ray tube display device due to characteristics such as lightness, thinness, and the like. As a representative example of the flat panel display device, there are a liquid crystal display (LCD) device and an organic light emitting diode (OLED) display device. Among them, the organic light emitting diode (OLED) display device may have better luminance and viewing angle, and does not require a back light, and thus can be implemented as an ultra-thin type, as compared with the liquid crystal display (LCD) device.

The above information disclosed in this Background section is only for enhancement of understanding of the background of the invention and therefore it may contain information that does not form the prior art that is already known in this country to a person of ordinary skill in the art.

### SUMMARY

Embodiments are directed to a flexible substrate, including a flexible base substrate, and a first passivation layer that is formed on one surface of the base substrate and made of a material having a coefficient of thermal expansion lower than that of the base substrate.

The flexible substrate may further include a second passivation layer that is formed on an opposite surface of the base substrate and made of a material having a coefficient of thermal expansion lower than that of the base substrate.

The coefficient of thermal expansion of the first passivation layer may be the same as that of the second passivation layer.

The coefficient of thermal expansion of the first passivation layer may be larger than that of the second passivation layer.

The coefficient of thermal expansion of the first passivation layer may be 4 to 13% smaller than that of the base substrate, and the coefficient of thermal expansion of the second passivation layer may be 5 to 18% smaller than that of the base substrate.

The coefficient of thermal expansion of the first passivation layer may be 5 to 18% smaller than that of the base substrate.

The base substrate may be made of polyimide.

The first passivation layer may be made of at least one of urethane, polystyrene, acryl, and PET.

Embodiments are also directed to a flexible display device, including the flexible substrate according to an embodiment, a display element that is formed on the flexible substrate to display a pixel, and an encapsulation layer that covers the display element.

The display element may be an organic light emitting diode.

### BRIEF DESCRIPTION OF THE DRAWINGS

Features will become apparent to those of skill in the art by describing in detail example embodiments with reference to the attached drawings in which:

FIG. 1 is a cross-sectional view schematically illustrating a flexible substrate according to an example embodiment.

FIG. 2 is a cross-sectional view schematically illustrating a flexible substrate according to an example embodiment.

FIG. 3 is a cross-sectional view illustrating a flexible display device according to an example embodiment.

FIG. 4 is a cross-sectional view illustrating details of the flexible display device of FIG. 3.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art. Like reference numerals refer to like elements throughout.

In the drawings, the thickness of layers, films, panels, regions, etc., may be exaggerated for clarity. In the drawings, for understanding and ease of description, the thickness of some layers and areas may be exaggerated. It will be understood that when an element such as a layer, film, region, or substrate is referred to as being “on” another element, it can be directly on the other element or intervening elements may also be present.

In addition, unless explicitly described to the contrary, the word “comprise” and variations such as “comprises” or “comprising” will be understood to imply the inclusion of stated elements but not the exclusion of any other elements. Further, in the specification, the word “on” means positioning on or below the object portion, but does not essentially mean positioning on the upper side of the object portion based on a gravity direction.

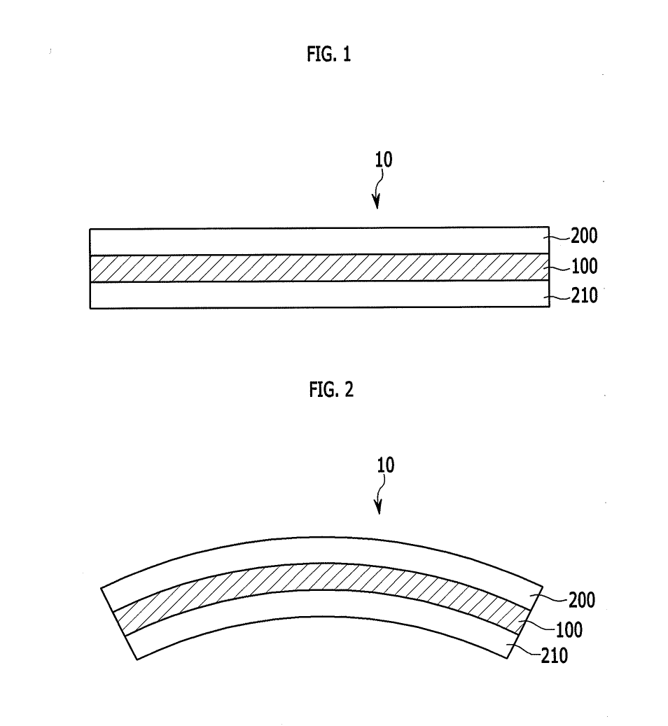

FIG. 1 is a cross-sectional view schematically illustrating a flexible substrate according to an example embodiment.

Referring to FIG. 1, a flexible substrate 10 according to an example embodiment is configured to include a flexible base substrate 100 and a first passivation layer 200.

According to the present example embodiment, the flexible base substrate 10 is a transparent substrate used in a general flexible display device and the base substrate 100 may be formed by a method of applying and thermosetting a liquid polymer material.

The base substrate 100 may be made of, e.g., polyimide, polycarbonate, polyacrylate, polyethersulfone, polyethylene terephthalate, polyethylene naphthalate, etc. Among them, the polyimide may be used at a process temperature of 450° C. or more, to thereby help minimize deterioration of a thin film transistor during the manufacturing of the thin film transistor.

According to the present example embodiment, the first passivation layer 200 may be formed on one surface of the base substrate 100. The first passivation layer 200 may be a member to supplement thermal stability of the base substrate 100. The first passivation layer 200 may be made of materials having a coefficient of thermal expansion lower than that of the base substrate 100.

When the base substrate 100 is exposed to a high temperature environment during the manufacturing process of the display device, the base substrate 100 is thermally expanded, such that components, such as a circuit unit, a display panel, and the like, which are formed on the base substrate 100, may be distorted and deformed. When the first passivation layer 200 is attached to a surface of the base substrate 100, the deformation of the base substrate 100 may be minimized due to the first passivation layer 200 even though the base substrate 100 is exposed to the high temperature environment.

The coefficient of thermal expansion of the first passivation layer 200 may be smaller than that of the base substrate 100 by 5 to 18%. When the coefficient of thermal expansion of the first passivation layer 200 is smaller than that of the base substrate 100 by a percentage less than 5%, the effects of the first passivation layer 200 may not be sufficient. When the coefficient of thermal expansion of the first passivation layer 200 is smaller than that of the base substrate 100 in excess of 18%, the thermal expansion rate between the first passivation layer 200 and the base substrate 100 may be too different, such that the two layers may be damaged or a delamination between the two layers may occur.

When the base substrate 100 is made of polyimide, the first passivation layer 200 may be made of one or more of urethane, polystyrene, acryl, or PET (polyethylene terephthalate). In an implementation, the first passivation layer 200 is prepared to have a coefficient of thermal expansion lower than that of polyimide by using these materials.

Referring to FIG. 1, a second passivation layer 210 may be formed on an opposite surface of the base substrate 100, i.e., opposite to the first passivation layer 200.

Like the first passivation layer 200, the second passivation layer 210 may be a member to supplement thermal stability of the base substrate 100. Like the first passivation layer 200, the second passivation layer 210 may be made of materials having a coefficient of thermal expansion lower than that of the base substrate 100. In an embodiment, both surfaces of the base substrate 100 are provided with the passivation layers 200 and 210, such that the thermal expansion of the base substrate 100 may be more effectively prevented.

In an implementation, the second passivation layer 210 may be made of the same material as the first protective layer 200. In this case, the coefficient of thermal expansion of the first passivation layer 200 may be the same as that of the second passivation layer 210. The passivation layers 200 and 210 having the same coefficient of thermal expansion are disposed on both surfaces of the base substrate 100, such that the base substrate 100 may keep a flat plane.

FIG. 2 is a cross-sectional view schematically illustrating a flexible substrate according to the example embodiment.

According to another example embodiment, the coefficient of thermal expansion of the first passivation layer 200 may be formed to be larger than that of the second passivation layer 210. In this case, since the coefficient of thermal expansion of the first passivation layer 200 is larger, the base substrate 100 may be concavely bent in a direction of the second passivation layer 210 as illustrated in FIG. 2.

In this case, the coefficient of thermal expansion of the first passivation layer 200 may be 4 to 13% smaller than that of the base substrate 100 and the coefficient of thermal expansion of the second passivation layer 210 may be 5 to 18% smaller than that of the base substrate 100. When the coefficients of thermal expansion of the first and second passivation layers 200 and 210 are in the stated range, the base substrate 100 may be stably bent while the distortion of the base substrate 100 is minimized.

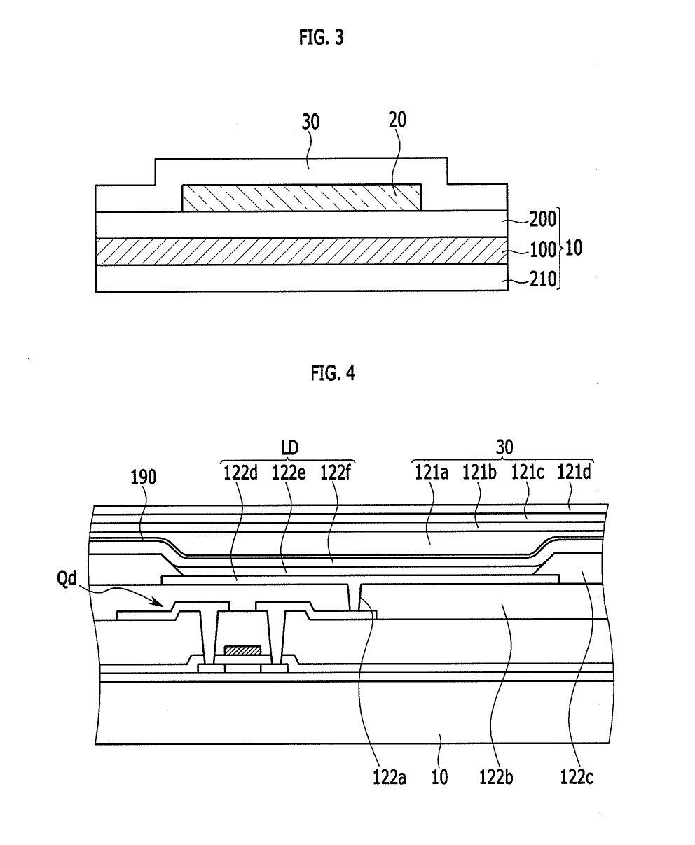

FIG. 3 is a cross-sectional view illustrating a flexible display device according to an example embodiment.

Referring to FIG. 3, the flexible display device is configured to include a flexible substrate 10, an organic light emitting diode 20, and a thin film encapsulation layer 30.

The flexible display device according to the example embodiment is not limited to the organic light emitting diode 20 as a display element and may be, e.g., a liquid crystal display element or an electrophoretic display (EPD) element.

A flexible substrate may be bent or extended due to heat, such that it may be difficult to precisely form thin film patterns of the thin film transistor, the light emitting element, a conductive wire, and the like, on the flexible substrate, and the flexible substrate may be damaged during movement. Therefore, the flexible substrate may suffer from subsequent processes in a state in which the flexible substrate is disposed on a support substrate (not illustrated).

In the present example embodiment, a wiring part (not illustrated) and the organic light emitting diode 20 are disposed on the flexible substrate 100. The wiring part transfers a signal to the organic light emitting diode 20 to drive the organic light emitting diode 20. The organic light emitting diode 20 emits light depending on the signal transferred from the wiring part.

The thin film encapsulation layer 30 is formed on the organic light emitting diode 20 to encapsulate the organic light emitting diode 20. If the organic light emitting diode 20 reacts to moisture or oxygen, the performance thereof may deteriorate. The thin film encapsulation layer 30 helps block and protect the organic light emitting diode 20 from the outside in order to reduce or prevent performance deterioration.

FIG. 4 is a cross-sectional view illustrating details of the flexible display device of FIG. 3. The organic light emitting diode 20 of FIG. 3, which is an organic light emitting diode (OLED), corresponds to an organic light emitting diode LD of FIG. 4.

Referring to FIG. 4, the organic light emitting diode LD includes a first electrode 122d, an organic light emitting layer 122e, and a second electrode 122f.

In the present example embodiment, the organic light emitting layer 122e may include an organic layer for to help transfer carriers, such as holes or electrons, to the light emitting layer, in addition to the light emitting layer that actually emits light. The organic layers may include one or more of, e.g., a hole injection layer (HIL) and a hole transport layer (HTL) disposed between the first electrode 122d and the light emitting layer, and an electron injection layer (EIL) and an electron transport layer (ETL) disposed between the second electrode 122f and the light emitting layer.

In the organic light emitting diode LD, when a predetermined voltage is applied to the first electrode 122d and the second electrode 122f, holes injected from the first electrode 122d move the light emitting layer via the hole transport layer (HTL) forming the light emitting layer, and electrons injected from the second electrode 122f are injected into the light emitting layer via the electron transport layer (ETL).

In this case, excitons are generated by a recombination of electrons and holes in the light emitting layer, and, as the excitons are changed from an excited state to a ground state, fluorescent or phosphorescent molecules of the light emitting layer emit light to form an image. The organic light emitting diode LD is disposed on the flexible substrate 10 and receives a signal from the wire part and displays an image based on the received signal. A pixel means a minimum unit for display of the image, and the organic light emitting diode (OLED) display device uses a plurality of pixels to display the image.

Generally, one pixel PX includes a switching transistor (not illustrated), a driving transistor Qd, a storage capacitor (not illustrated), and the organic light emitting diode LD.

A passivation layer 122b, which may be made of an inorganic or organic material, is formed on the driving transistor Qd. When the passivation layer 122b is made of the organic material, a surface thereof may be planarized. A via hole 122a, which exposes a part of the driving transistor Qd, is formed on the passivation layer 122b. The first electrode 122d is formed on the passivation layer 122b.

A pixel defining layer 122c covering a circumference of an edge of the first electrode 122d is formed on the passivation layer 122b.

In addition, a capping layer 190 as an organic layer, which covers and protects the second electrode 122f, may be formed on the second electrode 122f.

The thin film encapsulation layer 30 is formed on the capping layer 190. Herein, the thin film encapsulation layer 30 corresponds to the thin film encapsulation layer 30 of FIG. 3. The thin film encapsulation layer 30 helps encapsulate and protect the organic light emitting diode LD and the driving circuit unit, which are formed on the flexible substrate 10, from the outside.

The thin film encapsulation layer 30 includes organic layers 121a and 121c and inorganic layers 121b and 121d that are alternately stacked one by one. FIG. 4 illustrates the case in which, for example, two organic layers 121a and 121c and two inorganic layers 121b and 121d are alternately stacked one by one to configure the thin film encapsulation layer 121, but the present example embodiment is not limited thereto.

The inorganic layer may be made of aluminum oxide or silicon oxide and the organic layer may be made of epoxy, acrylate, urethane acrylate, and the like.

The inorganic layer helps prevent moisture and oxygen from penetrating into the light emitting element from the outside. The organic layer helps to mitigate an internal stress of an inorganic layer or fill a fine crack and a pin hole, and the like, of the inorganic layer. The foregoing structure materials of the inorganic layer and the organic layer are only an example, and the present example embodiment is not limited to the foregoing materials, and therefore various kinds of suitable inorganic layers and organic layers may be used.

The flexible display device may completed by separating the flexible substrate 10 from a support substrate.

By way of summation and review, a general flat panel display device may be formed on a glass substrate that may transmit light. A flat panel display device may be implemented to be thinner and lighter but should not break. A flat panel display device using a glass substrate may be vulnerable to external impact and may have degraded handling property during a manufacturing process.

A flexible substrate of a plastic optical film material may be selected as a material to replace the glass substrate. The flexible substrate may be thinner, lighter, stronger against impact, and conveniently carried, and further, may be relatively free of limitations of a space and a shape to secure various applications, as compared with glass-based flat type products. Thus, a demand for a flexible substrate has increased.

A flexible substrate of the plastic optical film material may have a low heat resistance. Thus, the flexible substrate according to an embodiment may be designed so as to accommodate a high temperature process in a manufacturing process for forming a thin film transistor of polysilicon or a process of depositing an electrode, a light emitting element, or the like, formed on the flexible substrate.

As described above, embodiments may provide a flexible substrate having thermal stability and a flexible display device including the same. According to example embodiments, a flexible substrate may provide thermal stability to prevent deformation due to heat during the manufacturing process of the display device, and may be stably bent while using the flexible display device.

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims.

<Description of symbols>

| | |
|---|---|
| 10: Flexible substrate | 20: Organic light emitting diode |
| 30: Thin film encapsulation layer | 100: Base substrate |
| 200: First passivation layer | 210: Second passivation layer |

What is claimed is:

1. A flexible substrate, comprising:
a flexible base substrate; and
a first passivation layer that is formed on one surface of the base substrate and made of a material having a coefficient of thermal expansion lower than that of the base substrate.

2. The flexible substrate of claim 1, further comprising a second passivation layer that is formed on an opposite surface of the base substrate and made of a material having a coefficient of thermal expansion lower than that of the base substrate.

3. The flexible substrate of claim 2, wherein the coefficient of thermal expansion of the first passivation layer is the same as that of the second passivation layer.

4. The flexible substrate of claim 2, wherein the coefficient of thermal expansion of the first passivation layer is larger than that of the second passivation layer.

5. The flexible substrate of claim 4, wherein:
the coefficient of thermal expansion of the first passivation layer is 4 to 13% smaller than that of the base substrate, and
the coefficient of thermal expansion of the second passivation layer is 5 to 18% smaller than that of the base substrate.

6. The flexible substrate of claim 1, wherein the coefficient of thermal expansion of the first passivation layer is 5 to 18% smaller than that of the base substrate.

7. The flexible substrate of claim 1, wherein the base substrate is made of polyimide.

8. The flexible substrate of claim 7, wherein the first passivation layer is made of at least one of urethane, polystyrene, acryl, and PET.

9. A flexible display device, comprising:
the flexible substrate as claimed in claim 1;
a display element that is formed on the flexible substrate to display a pixel; and
an encapsulation layer that covers the display element.

10. The flexible display device of claim 9, wherein the display element is an organic light emitting diode.
